(19) United States
(12) Patent Application Publication
(10) Pub. No.: US 2002/0176453 A1
(43) Pub. Date: Nov. 28, 2002

(54) System for fine tuning of a wavelength produced by a laser diode

(76) Inventor: Yoav Asa, Ganei Tikva (IL)

Correspondence Address: NATH & ASSOCIATES, 1030 15th STREET, 6TH FLOOR, WASHINGTON, DC, 20005, US

(21) Appl. No.: 10/139,316

(22) Filed: May 7, 2002

(30) Foreign Application Priority Data
May 10, 2001 (IL) 143072

(51) Int. Cl. H01S 3/098; H01S 3/13

(52) U.S. Cl. 372/18; 372/29.011

(57) ABSTRACT

A system for fine tuning a laser diode to selectively lock it at more than one optical wavelengths, wherein the laser diode is equipped with an optical wave-locker based on a pair of photo diodes. The system comprises a control unit controlling at least one reference circuit having adjustable resistance and associated with the photo diodes; the control unit is capable of selectively switching, to said photodiodes, the mentioned at least one reference circuit and adjusting the resistance thereof for selecting a particular wavelength to which the laser is to be locked. The system further comprises a comparing unit for processing electric signals produced by said photodiodes in combination with the reference circuit(s) if switched in, and a feedback circuit for adjusting the laser's radiation to said particular wavelength based on a difference between the electric signals.

### FIELD OF THE INVENTION

The present invention relates to a technology for fine tuning of wavelength of radiation produced by a laser diode and therefore to a technology of rendering a laser diode capable of emitting more than one optical wavelengths.

### BACKGROUND OF THE INVENTION

Lasers have long been known in the art for a wide variety of uses. These sources of light are arranged to function at a certain predetermined wavelength. In some applications, it is unimportant whether the wavelength of the laser remains essentially constant over time. However, in other applications, such as optical telecommunications, and medical lasers, it is crucial that the preset wavelength be maintained throughout the use of the laser. This is necessary due to aging of the laser, as well as the environmental effect of temperature, two of the major factors affecting laser wavelength.

A number of proposals have been made in the literature as to ways to monitor and control lasers. In particular, much research has been conducted in the area of telecommunications over optical fiber lines.

According to the most widely used method, wavelength of a laser diode may be adjusted (or locked to a required value) by temperature monitoring. One laser may be tuned to different wavelengths by successively applying to it respective different temperatures. As a rule, for obtaining a laser diode assembly capable of providing more than one optical channels simultaneously, a number of laser diodes are respectively subjected to different degrees of controlled cooling to cause them producing optical radiation at different wavelengths in accord.

Alternatively or in addition, an outside reference can be used, for example, from a synchronized etalon filter which provides a reference at a standardized wavelength, or from a frequency stabilized master laser.

One known principle of stabilizing frequency of a laser using a Fabry Perot etalon filter is described in U.S. Pat. No. 3967211. There is employed a variation in position of interference patterns which results from a variation in laser beam frequency passing through a Fabry Perot etalon filter.

Nortel Networks® produces a series of etalon stabilized lasers (such as LCM155W-20A), where the laser diode can be locked at a particular wavelength using two monitor photodiodes each with a different spectral characteristic.

In the modem market of optical components for WDM (Wavelength Division Multiplexing) and DWDM (Dense WDM), there are devices where a single laser provided with etalon filter(s) is capable of producing multiple optical channels, i.e. optical radiation at more than one stable optical wavelengths. For example, there is known an E-TEK's Fabry-Perot wavelength locker which constitutes a thermally stable etalon based device used to stabilize laser sources for high-density WDM applications. Due to a periodic light response characteristics of the etalon, the device can operate at any wavelength specified by ITU (International Telecommunication Union) for optical channels, with accuracy of about ±2.5 GHz. The device should be preliminarily set to one of the required wavelengths.

Nevertheless, there is still a possibility that any laser diode preliminarily set to a particular wavelength, will require fine tuning. This may easily happen when the temperature monitoring becomes inaccurate in WDM systems with close optical channels (i.e., systems with a small wavelength spacing). On the other hand, the trend in optical telecommunications field predicts introducing new standard optical channels, so even smaller controllable spacing could be required soon.

### OBJECT OF THE INVENTION

It is an object of the present invention to provide a system for fine tuning of a laser diode for rendering it ability of producing multiple optical channels with high accuracy.

Another object of the invention would be a fine tunable laser assembly where a single laser is capable of producing multiple optical channels with high accuracy.

### SUMMARY OF THE INVENTION

The above object can be achieved by providing a system for fine tuning a laser diode to selectively lock it at more than one optical wavelengths, wherein the laser diode is equipped with an optical wave-locker based on a pair of photo diodes; the system comprising a control unit controlling at least one reference circuit having adjustable resistance and associated with said photo diodes, said control unit being capable of selectively switching, to said photodiodes, said at least one reference circuit and adjusting the resistance thereof for selecting a particular wavelength to which the laser is to be locked, the system further comprising a comparing unit for processing electric signals produced by said photodiodes in combination with the reference circuit(s) if switched in, and a feedback circuit for adjusting, based on the difference between said electric signals, the laser's radiation to said particular wavelength.

In the fine tuning system, the reference resistors may be part of the comparing unit, or a part of the control unit. Alternatively, the reference resistors can be selectively connectable to said photo diodes before the comparing unit.

According to the second aspect of the invention, there is provided a finely tunable laser assembly selectively lockable at more than one optical wavelengths, the assembly comprises a laser diode equipped with a pair of photodiodes, the assembly also comprising a control unit for controlling at least one reference circuit having adjustable resistance, said control unit being capable of selectively switching, to said photo diodes, said at least one reference circuit and adjusting the resistance thereof for selecting a particular wavelength to which the laser is to be locked, the assembly further comprising a comparing unit for processing electric signals produced by said photo-diodes in combination with the reference circuit(s) if switched in, and a feedback circuit for adjusting, based on the difference between said electric signals, the laser's radiation to said particular wavelength.

While the system for fine tuning of a laser diode is essentially the system defined in the first paragraph of the summary, the laser diode assembly (to be tuned) may be different. For example, the laser diode assembly may be manufactured according to the following modifications:

According to the preferred embodiment of the assembly, it comprises at least one etalon filter having a specific spectral response to each of said optical wavelengths and adapted to illuminate at least one of said photodiodes. For example, the photodiodes may have equal spectral characteristics if they are arranged to be unequally illuminated by said at least one etalon filter.

According to another embodiment of the invention, each of the photodiodes has a different spectral characteristic.

The assembly where the photodiodes have different spectral characteristics may also comprise a single etalon filter having a specific spectral response to each of said optical wavelengths and adapted to equally illuminate both of said photodiodes.

However, in the assembly where a single said etalon filter is illuminated by the laser diode and arranged to illuminate the pair of photo diodes, these two photo diodes may be equal i.e., have identical spectral characteristics. If the diodes are equal, they usually receive different light signals from the etalon filter due to its assymmetric shape or asymmetric position with respect to the photo diodes, in order to form different spectral responses.

In yet a further embodiment, the laser assembly may comprise the laser diode arranged to illuminate two etalon filters respectively connected to two photo diodes to produce different spectral responses which are usually equal at the wavelength to which the laser is to be locked.

If any of such laser assemblies (wavelength lockers) is provided with the system for fine tuning, the wavelength to be stabilized can easily be changed, so the laser acquires the property of emitting different wavelengths upon performing the setting in the fine tuning system.

The etalon filter may be adapted to be illuminated with the laser emitted light either from the back facet of the laser (which is preferable), or from its main facet, upon splitting the beam for the purposes of monitoring.

The etalon filter may constitute an etalon with a periodic characteristic which is connected to a pair of photo diodes one of which is a reference diode. (Say, the laser assembly is the E-TEK's Fabry-Perot wavelength locker). By switching the above-proposed fine tuning system to such a laser assembly, the wavelengths, which can be locked to, may be changed and/or fulfilled with additional stabilized wavelengths.

Likewise, the Inventor has realized that an optical device in the form of an etalon stabilized laser with a back facet monitor (which devices are widely available from the industry) can easily be adapted to produce multiple optical channels by combining thereof with the proposed fine tuning system. An example of such a device is a Nortel Networks LCM155W-20A transmitter (2.5 Gb/s Co-packaged Etalon Stabilised Laser and III-V Mach-Zehnder).

Any presently known optical transmitter comprising an integrated laser diode is unable of producing optical channels with spacing there-between less than the frequency difference 100 GHz since the accuracy of controlled cooling, used to maintain the required wavelength, is not sufficient. In view of this, the proposed fine tuning system enables not only fine adjustment of the wavelengths which are to be emitted by the lasers, but addresses the above-mentioned problem by allowing further compression of the optical channels in the WDM systems, thereby increasing capacity of optical transmission lines.

The laser assembly comprising the above-specified or a similar transmitter and the fine tuning system according to the invention, will be adjustable to any wavelength from those the laser is able to emit. The laser assembly will therefore be capable of producing multiple optical channels with very small spacing.

Other aspects and further details of the invention will become apparent as the description proceeds.

### BRIEF DESCRIPTION OF THE DRAWINGS

The invention can be described and explained with the aid of the following non-limiting drawings in which:

FIGS. 1a, 1b, 1c and 1d are schematic block-diagrams of various modifications of laser assemblies comprising monitoring photo diodes.

FIGS. 2a, 2b and 2c are functional diagrams explaining co-operation of etalon filter(s) and photo-diodes in case the former have a spectral response with a single maximum in the region of the required wavelength, and the way of using the fine tuning system for locking a laser assembly at any desired wavelength.

FIG. 2d is a functional diagram schematically explaining how the fine tuning system can be used for precise adjustment of a wavelength at which a laser assembly with a multi-peak etalon filter is locked.

FIG. 3 is a schematic block-diagram illustrating one embodiment of the fine tuning system serving the laser assembly according to the invention.

FIG. 4 is a particular example of a system implementing the proposed invention by utilizing one of optical component microcircuits available from the industry.

### DETAILED DESCRIPTION OF THE INVENTION

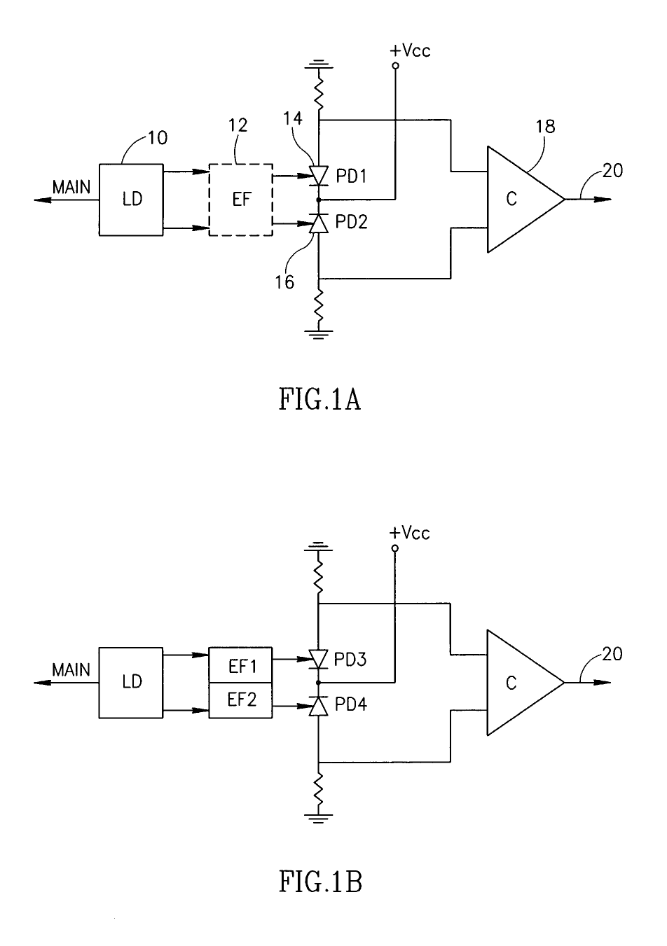

FIGS. 1a-1d are schematic diagrams of non-limiting examples of laser diode assemblies with a wavelength locker comprising a pair of photodiodes. As can be understood from the diagrams, in most cases a laser diode (LD) illuminates one or more etalon filters (EF) with a portion of its optical radiation and the etalon filter(s) illuminate photo diodes (PD) with the filtered bandwidth comprising the wavelength to be locked to. FIG. 1a, where the etalon filter EF is shown by dotted lines (demonstrating that EF may be absent), is intended for illustrating also an option when the pair of photodiodes having different spectral responses is directly illuminated by a portion of the laser's radiation. FIG. 1d shows another option where one photodiode of the pair is illuminated by a portion of the laser's radiation and not by the light outgoing from EF. It should be emphasized that the photodiodes or the etalon filter, as the case may be, are never illuminated directly by the laser output, but rather from the laser's back facet or by splitting the laser's main facet radiation.

In general, the etalon filter EF (for example, a Fabry-Perrot filter) is intended for cutting such an optical band from the spectrum of the laser radiation, which includes the wavelength(s) to which the laser LD is intended to be locked. For locking the laser at a single wavelength, the etalon filter may have a single-peak spectrum response characteristic. For selectively locking the laser at a number of wavelengths, there is known an etalon filter having a so-called multi-peak characteristic. However, both for fine tuning the selected wavelength, and for obtaining an additional wavelength (optical channel) to which the laser assembly is not set in advance, the proposed fine tuning system can be used.

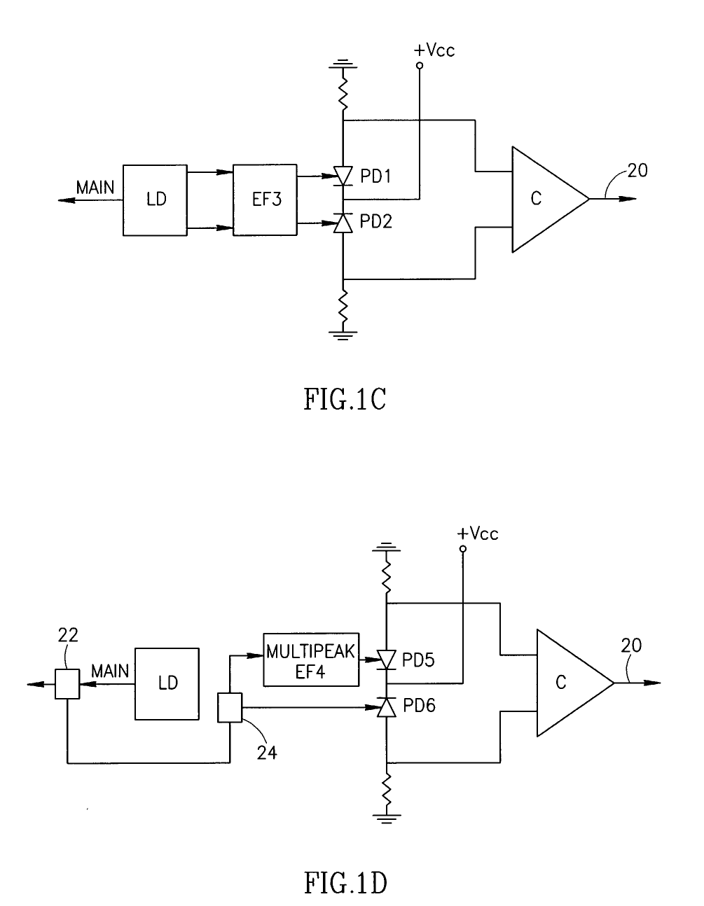

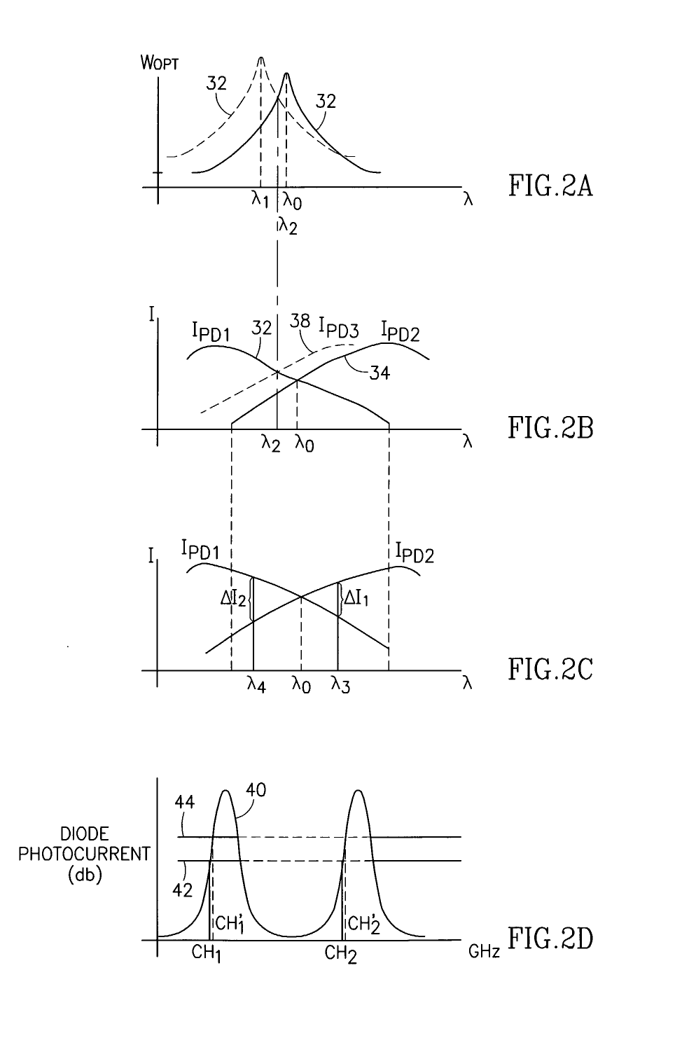

Physical processes on which the wavelength lockers 1a-1c are based can be explained with the aid of diagrams shown in FIGS. 2a-2b.

According to one option shown in FIG. 1a, the etalon filter EF 12 (for example a Fabry- Perot filter) cuts out a specific narrow sub-band of optical wavelengths from the radiation band emitted by the laser LD 10 (See FIG. 2a, a solid curve 30 with the peak at the central wavelength λ₀). This particular radiation is fed onto two photo diodes PD1 and PD2 having different spectral responses or opto-electric characteristics, so they produce differing electric current signals 32 and 34 (See FIG. 2b) in response to the power of incident light coming from EF. It should be noted that the curves 32 and 34 of optical spectral responses overlap (are equal) at one wavelength from the sub-band; this wavelength is the convenient one for locking the laser at the very point λ₀ where the spectral responses are equal, and the known lockers work using this principle. Comparator C (marked 18) can be added to determine the moment where the currents via the photodiodes are equal, taking place at the wavelength equal to λ₀, and issue a locking signal 20. As mentioned before, the EF 12 may be absent, if different spectral responses of the photodiodes are such that enable comparing currents via the photodiodes even when illuminated directly by a portion of the laser diode radiation.

FIG. 1b illustrates an option where two etalon filters EF1 and EF2, slightly differing by their peaks, are used instead of one common etalon filter 12. The characteristic of the second filter is illustrated in FIG. 2a by the dotted line 36 having a center wavelength λ₁. The diodes PD3 and PD4 may have equal or non-equal spectral responses. FIG. 2b shows a dotted curve 38 of the optical spectral response of the photo diode which is illuminated by the etalon filter having the characteristic 36. The locking can then be performed at the wavelength λ₂.

FIG. 1c illustrates a case where the etalon filter EF3 is asymmetrically shaped and placed with respect to the photo diodes, so, due to different incident angles of the light illuminating the etalon EF3, the photodiodes produce different spectral responses to the light ougoing from the etalon. The character of the currents flowing through the photo diodes in this case can be generally illustrated by the same FIG. 2c.

FIG. 1d illustrates a wavelength locker with another type of the etalon filter—so-called multi-peak etalon filter EF4. The latter illuminates one photo diode PD5, while the photo diode PD6 is illuminated by a portion of light derived by splitters 22 and 24 from the laser radiation emitted via the main facet of the laser, and causing a constant reference current through PD6. The processes taking place in the wavelength locker of FIG. 1d are illustrated by diagrams of FIG. 2d. Curve 40 shows the current flowing through the diode PD5, and curve 42—through the diode PD6. The comparator C is able to lock either at one standardized channel Ch1 (having its specified wavelength), or at another standardized channel Ch2.

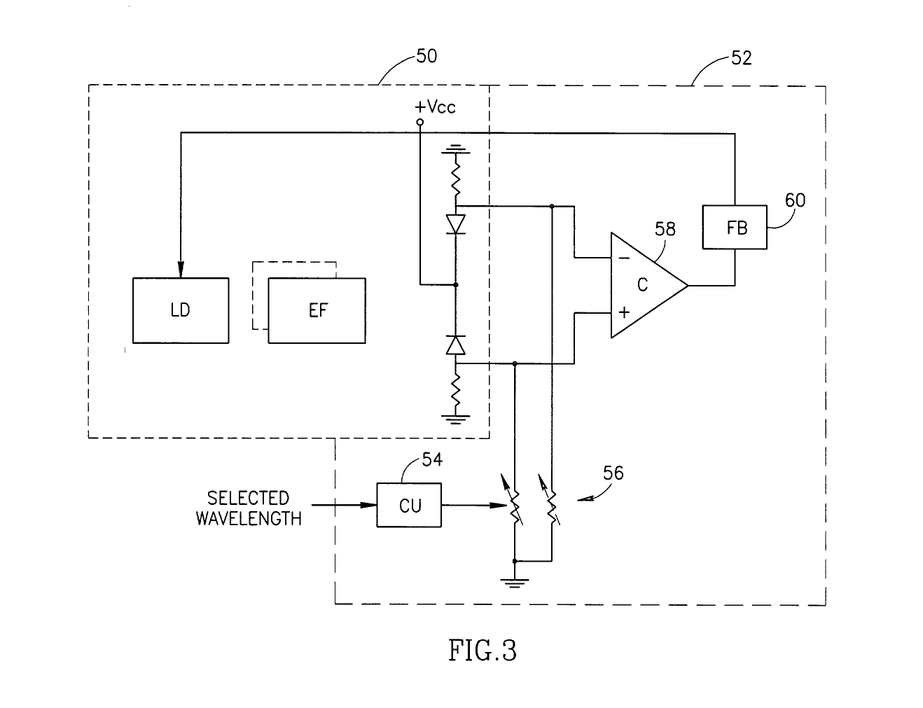

FIG. 3 illustrates a schematic block-diagram of a fine tuning system proposed by the Inventor for fine tuning wavelength lockers with a pair of photo diodes, to make a laser diode assembly producing additional highly precise and dense optical channels. The diagram comprises a block 50 being a wavelength locker according to any one of the embodiments shown in FIGS. 1a-1d or the like, comprising a laser and a pair of photodiodes. The wavelength locker 50 can be tuned to obtain additional channels by connecting it to a fine tuning system 52. The fine tuning system comprises a control unit (CU) 54, a pair of reference circuits 56 controlled by the CU 54 and having at least one adjustable resistance, a comparing unit 58 and a feedback circuit 60. Though illustrated separately in the diagram, the reference circuits 56 may form integral part of the control unit 54, as well as of the comparing unit 58.

The system 52 enables locking the laser LD at any particular wavelength it is capable to emit, and the locking is provided by maintaining the laser at a wavelength where the spectral responses of the photo diodes differ by a preliminarily calibrated value.

In other words, a graph of current, flowing via one of the photodiodes illuminated by the sub-band of wavelengths produced by the etalon, differs from a graph of current flowing via the other photodiode. The inventor has realized that for any selected wavelength on the axis of the sub-band conducted by the etalon filter there can be found a particular ratio of electric signals produced by the two photo diodes in response to that wavelength. The ratio(s) can be obtained by calibration. Further, for any such particular ratio a combination of the reference elements in the circuits 56 can be found which will cause the comparing unit 58 to react on the ratio by issuance of a control signal to the feedback circuit 60, thereby locking the laser at the selected wavelength corresponding to the mentioned particular ratio. The principle of operation of the fine tuning system can be illustrated using FIGS. 2c and 2d. FIG. 2c explains the tuning system's action in case the wavelength locker is one of (or similar to) those shown in FIGS. 1a-1c. To distinguish any wavelength around the central wavelength, there can be measured in advance (calibrated) the difference between the currents via the pair of photodiodes—say, PD1 and PD2 (ΔI1, ΔI2, . . . ). If the comparing unit 58 is adjusted to react to these differences as to “0”, the laser can be locked to any specific selected wavelength. In order to make the comparing unit react to the known differences as desired, the reference circuits 56 can be selectively connected and adjusted by the control unit CU.

Curve 44 in FIG. 2d illustrates how the fine tuning system can be used in a laser assembly comprising a multi-peak etalon filter (see FIG. 1d) for locking to a number of wavelengths. To this end, the etalon filter characteristic is used together with the characteristic of a reference photodiode PD6 illuminated by the laser. By selectively switching and adjusting reference circuits (56, see FIG. 3), to the photodiodes PD6 and/or PD5 the channels to be locked to can be smoothly and accurately shifted (say, to Ch1′, Ch2′), so that not only the fine tuning of multiple channels can be performed, but any combination of the optical channels (both preliminarily stated, and adjusted) can be provided by the wavelength locker.

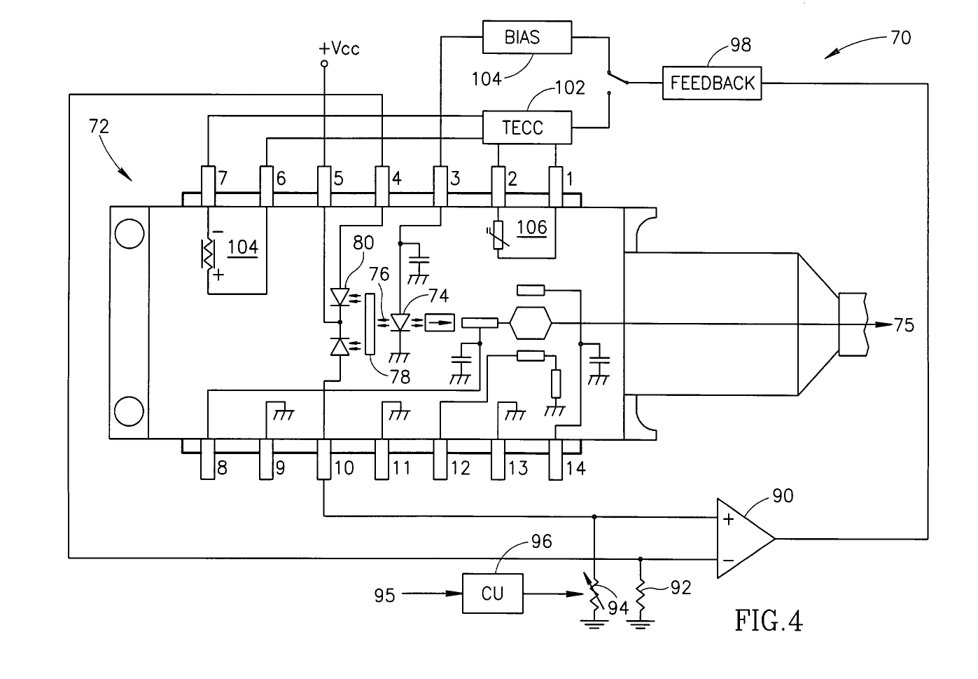

FIG. 4 illustrates one embodiment of the fine tuning system 70 combined with a wavelength locker 72 and thereby presenting a laser assembly according to the invention. The wavelength locker 72 may constutute, for example, the Etalon stabilized laser of Nortel Networks®, say LCM155W-20A.

The wavelength locker 72 comprises a laser diode (LD) 74 capable of emitting radiation. The main portion 75 of the laser radiation passes via a Mach-Zehnder modulator and isolator and is then emitted from the outlet aperture of the device. Portion 76 of the radiation is directed to an etalon filter 78 from the back facet of the laser.

In this locker, the etalon filter 78 is a single-peak etalon which is usually lockable to a single wavelength. The optical radiation conducted though the etalon filter 78 simultaneously illuminates a photo diode 80 (PD1) and a photo diode 82 (PD2). Cathodes of the photo diodes are fed from one power source +Vcc. Electric signals on the anodes of the photo diodes are compared by a comparing unit 90 of the fine tuning system. However, the signals are not compared and processed as are, but in combination with biases if provided by reference circuits 92 and 94 which can be switched by a control circuit 96. According to a command 95 defining a selected wavelength, the control circuit 96 connects one or more of elements of the reference circuits (resistors and other components) to the photo diodes 80 and/or 82. Actually, to perform fine tuning of the wavelength to which the laser is locked, the control circuit 96 causes a pre-calibrated change in the reference circuits thereby adjusting their bias and shifting the balance of the comparing unit 90. Resulting signals are compared by the unit 90 and when it equals to zero (i.e., signals at the two inputs are equal), the laser is considered to be locked to the selected wavelength. If not, the comparing unit 90 issues a corresponding discrepancy signal to a feedback circuit 98. The function of the feedback circuit is to adjust the laser's 74 wavelength based on the value and sign of the discrepancy signal. Changes in the comparing unit 90 cause the feedback circuit 98 to affect the laser diode 74 either by controlled cooling, or by altering the laser's bias. The feedback circuit is connected to the Thermo-Electric Cooler circuit (TECC) 102 coupled to a thermistor 106. The cooling can be performed with the aid of a TECC block 102 responsible for changing the laser's temperature, using the internal thermoelectric cooler 104 in the wavelength locker. Adjustment of the laser bias current is performed through the Bias block 106 which affects the laser diode internal circuit.

The above-described laser assembly may be easily adapted for the use in WDM optical systems where additional optical channels are required, or where the optical channels are to be finely tuned.

1. A system for fine tuning a laser diode to selectively lock it at more than one optical wavelengths, wherein the laser diode is equipped with an optical wave-locker based on a pair of photo diodes; the system comprising a control unit controlling at least one reference circuit having adjustable resistance and associated with said photo diodes, said control unit being capable of selectively switching, to said photodiodes, said at least one reference circuit and adjusting the resistance thereof for selecting a particular wavelength to which the laser is to be locked, the system further comprising a comparing unit for processing electric signals produced by said photodiodes in combination with the reference circuit(s) if switched in, and a feedback circuit for adjusting the laser's radiation to said particular wavelength based on a difference between said electric signals.

2. The system for fine tuning according to claim 1, wherein the reference resistors are part of the comparing unit.

3. A finely tunable laser assembly selectively lockable at more than one optical wavelengths, the assembly comprises a laser diode equipped with a pair of photodiodes, the assembly also comprising a control unit for controlling at least one reference circuit having adjustable resistance, said control unit being capable of selectively switching, to said photo diodes, said at least one reference circuit and adjusting the resistance thereof for selecting a particular wavelength to which the laser is to be locked, the assembly further comprising a comparing unit for processing electric signals produced by said photo-diodes in combination with the reference circuit(s) if switched in, and a feedback circuit for adjusting, based on the difference between said electric signals, the laser's radiation to said particular wavelength.

4. The finely tunable laser assembly according to claim 3, comprising at least one etalon filter having a specific spectral response to each of said optical wavelengths and adapted to illuminate at least one of said photodiodes.

5. The assembly according to claim 3, wherein each of the photodiodes has a different spectral characteristic.

6. The assembly according to claim 4, wherein each of the photodiodes has a different spectral characteristic.

7. The assembly according to claim 4, wherein said at least one etalon filter is adapted to be illuminated with the laser light emitted from the back facet of the laser.

8. The assembly according to claim 4, wherein said at least one etalon filter constitutes an etalon with a periodic characteristic, connected to a pair of photo diodes one of which is a reference diode.

9. The assembly according to claim 3, wherein said laser diode and said two photodiodes form part of an etalon stabilized laser with a back facet monitor.

10. The assembly according to claim 3, adapted for the use in WDM optical systems.
